(19) United States
(12) Patent Application Publication
(10) Pub. No.: US 2005/0094828 A1
(43) Pub. Date: May 5, 2005

(54) Bass boost circuit

(76) Inventor: Yoshitsugu Sugimoto, Kamifukuoka-shi (JP)

Correspondence Address: ANTONELLI, TERRY, STOUT & KRAUS, LLP, 1300 NORTH SEVENTEENTH STREET, SUITE 1800, ARLINGTON, VA, 22209-9889, US

(21) Appl. No.: 10/975,438

(22) Filed: Oct. 29, 2004

(30) Foreign Application Priority Data
Oct. 30, 2003 (JP) 2003-369735

(51) Int. Cl. H03G 5/00; H03G 9/00

(52) U.S. Cl. 381/98; 381/102

(57) ABSTRACT

A bass boost circuit of the present invention changes simultaneously the amplification gain in the voltage-controlled amplifier, and the cut-off frequency of the low-pass filter according to level of bass component of incoming signal. It does not become over boost state, and sound such as “flop” or “overshoot” is canceled, it will further be hard being fallen out by middle range of frequency, and there is advantage that vocal and the like can tend to be heard, even when small signal is inputted.

### BACKGROUND OF THE INVENTION

The present Invention relates to bass boost circuit to which gain and cut-off frequency of the bass component are changed according to input level of audio signal.

Conventionally, in the field of audio signal processing technology, in order that man's hearing might rectify characteristic of being hard coming to catch bass sound at the time of small volume, bass boost circuit 10A as shown in FIG. 5 is proposed (for example, referring to Japanese Unexamined Patent Publication No. 145992/1993). This circuit extracts bass signal from audio signal inputted from input terminal 1 with low pass filter 2, detects it in detector circuit 3, and amplifies level of bass signal in voltage-controlled amplifier 6 according to that detection output. About audio signal at large, in adding circuit 7, bass signal created by above-mentioned bass boost circuit 10A and signal which raised level of treble with high pass filter 5 for treble boost were added, and it was outputting to output terminal 8.

By the bass boost circuit, the lower the level of bass of input signal becomes, the larger the amplification factor of the bass becomes, so that bass compensation on audibility is performed effectively.

Although there is individual difference in the range of frequency which man can perceive as a sound, and strength, about frequency, it may be between about 20 Hz and about 20 kHz. Although range about sound intensity changes with frequency, generally it is shown by loudness curve, calls maximum which can be perceived threshold of feeling, and gives full realization to ear to strong sound beyond this. Threshold of feeling is hardly influenced by frequency, but is about 120 dB in sound pressure level. Calling the minimum level noticed as a sound threshold of audibility, this produces remarkable difference by people. However, threshold of audibility becomes high as the frequency of sound comes to be low, and sensitivity of ear worsens, while threshold of audibility is low near between 2 kHz and 4 kHz of frequency, namely, sensitivity of ear is good for many people.

That is, since an ear of human being has variable threshold of audibility according to frequency, even if it gives sound of the same strength physically, if frequency is different, the same loudness will not hear it sensuously. When sound is strong, loudness does not almost have difference by frequency, but if sound becomes weak, loudness of low frequency region will quite reduce and it will come to feel weaker than the signal level. Therefore, there is phenomenon in which sounds of bass differ between turning down the volume and enlarging the volume, and tone changes also about complex sound.

Then, according to level of input signal, amplification factor of bass is controlled by bass boost circuit as shown in FIG. 5, and bass compensation on audibility at the time of small volume is performed effectively. Even when speaker of small caliber is used by combining such a boost circuit with surround-sound circuit (for example, referring to Japanese Unexamined Patent Publication No. 354595/2002), it can obtain feeling of spread more than aperture of speaker, and massive of bass.

### SUMMARY OF THE INVENTION

However, when 6 dB or more of basses (for example, frequency of about 100 Hz which a human being feels as bass most) was amplified focusing on frequency near 100 Hz according to level of input signal, or level of bass component, although bass had come out, it changed into state of over boost without acoustic effect, and it turned out that it is accompanied especially by change of tone as a result of experiment. It also turned out that there is fault only volume of bass is amplified, it will be fallen out by middle range of frequency, and vocal and the like stops being able to hear easily. Thus, when small signal is inputted in conventional boost circuit, as a result of emphasizing only bass which will be in over boost state and does not have acoustic effect but sound such as “flop” or “overshoot”, there was problem that change of tone is produced, or it will be fallen out by middle range of frequency and vocal and the like stopped being able to be audible easily.

An object of the present invention is offering boost circuit where it will not be in over boost state, but will be hard being fallen out by middle range of frequency, and vocal and the like can tend to be heard, even when small signal is inputted.

The bass boost circuit of the present invention is charactorized by comprising: a low-pass filter extracting bass component of incoming signal, a detector circuit inputting and detecting output signal of the low-pass filter, a low-pass filter of variable cut-off frequency inputting the incoming signal and outputting bass component, wherein cut-off frequency is controlled according to level of output signal of said detector circuit, and a voltage-controlled amplifier inputting the output signal of the low-pass filter of variable cut-off frequency and outputting bass boost output signal, wherein gain of the output boost signal is controlled according to level of output signal of the detector circuit.

Further, the bass boost circuit of the present invention is preferably comprising the low-pass filter of variable cut-off frequency which is controlled by output signal of said detector circuit so that the cut-off frequency becomes low as the output signal level of said low-pass filter is low, and the voltage-controlled amplifier which is controlled by output signal of said detector circuit so that the gain becomes high as the output signal level of said low-pass filter is low.

Further, the bass boost circuit of the present invention may include an averaging circuit which outputs average value of output signal of the low-pass filter or a maximizing circuit which outputs maximum of output signal of the low-pass filter instead of the detector circuit in the abaove-mentioned bass boost circuit.

The cut-off frequency of said low-pass filter is preferably set up among between 50 Hz and 600 Hz in the above-mentioned bass boost circuit.

The variability range of cut-off frequency of the low-pass filter of variable cut-off frequency is preferably set as from 10 to 600 Hz in the above-mentioned bass boost circuit.

Further, the connection order of the low-pass filter of variable cut-off frequency and the voltage-controlled amplifier may be reversed, or the low-pass filter of variable cut-off frequency and the voltage-controlled amplifier may be unified in the above-mentioned bass boost circuit.

The bass boost circuit of the present invention is able to input signal which added two audio signal of right and left channel as the incoming signal, and added the bass boost output signal to each audio signal of the right and left channel.

### BRIEF DESCRIPTION OF THE DRAWINGS

FIG. 1 is a block diagram of the boost circuit of Embodiment 1.

FIG. 2 is a frequency characteristic figure of gain of the boost circuit of Embodiment 1.

FIG. 3 is a concrete circuit diagram of the boost circuit of Embodiment 1.

FIG. 4 is a block diagram of voice circuit of two channels of Embodiment 2.

FIG. 5 is a block diagram of a conventional boost circuit.

### DETAILED DESCRIPTION

The Inventor was able to solve the above-mentioned problem by changing simultaneously amplification gain in voltage-controlled amplifier, and cut-off frequency of low-pass filter according to level of bass component of incoming signal, as a result of repeating various experiments. Hereafter, it explains in detail.

### Embodiment 1

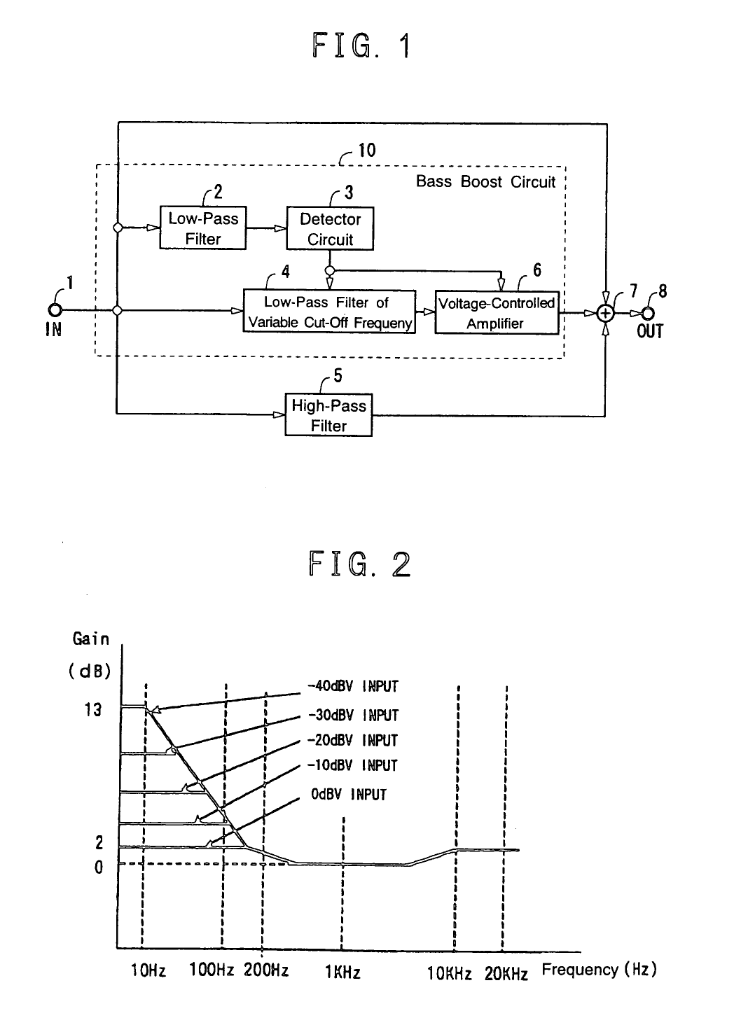

FIG. 1 is a schematic diagram showing a boost circuit of Embodiment 1 of the present invention. The boost circuit of Embodiment 1 consists of input terminal 1 of audio signal, low-pass filter 2 of which cut-off frequency was set up among between 50 and 600 Hz, detector circuit 3, low-pass filter of variable cut-off frequency 4 of which cut-off frequency can be changed between, for example, 10 and 600 Hz, high-pass filter 5 of which cut-off frequency was set up among between 10 kHz and 20 kHz, voltage-controlled amplifier 6 where the gain is controlled by control voltage, adding circuit 7, and output terminal 8 of audio signal. Bass boost circuit 10 comprises low-pass filter 2, detector circuit 3, low-pass filter 4 of variable cut-off frequency, and voltage-controlled amplifier 6.

Audio signal inputted from input terminal 1 is detected in detector circuit 3, after bass signal is extracted by low-pass filter 2. According to output level of the detector circuit 3, low-pass filter 4 of variable cut-off frequency and voltage-controlled amplifier 6 are controlled. When detection power level is low, cut-off frequency of low-pass filter 4 of variable cut-off frequency becomes low, and it becomes high when the power level is high. When detection power level is low, the gain of voltage-controlled amplifier 6 becomes high, and it becomes low when the power level is high. Thus, the cut-off frequency and the gain are simultaneously controlled about bass component, and audio signal which goes via low-pass filter 4 of variable cut-off frequency and voltage-controlled amplifier 6 is inputted into adding circuit 7. On the other hand, treble signal of audio signal inputted from input terminal 1 is extracted by high-pass filter 5, and is added in adding circuit 7. Input terminal 1 is connected to direct adding circuit 7. Therefore, from adding circuit 7, bass signal of which cut-off frequency and gain was controlled according to bass level, usual signal with which frequency characteristic is not adjusted, and treble signal are added and output to output terminal 8.

FIG. 2 is a graph which shows an example of the frequency characteristic of gain of audio signal output to output terminal 8. Thus, about bass signal, even if incoming signal level changes and gain changes, it operates so that gain change of frequency near 100 Hz may be suppressed to the minimum. Consequently, even when small signal is inputted, it will not be in over boost state, and sound such as “flop” or “overshoot” is also canceled, middle range of frequency is further hard coming to be fallen out, and vocal and the like can become easy to be heard.

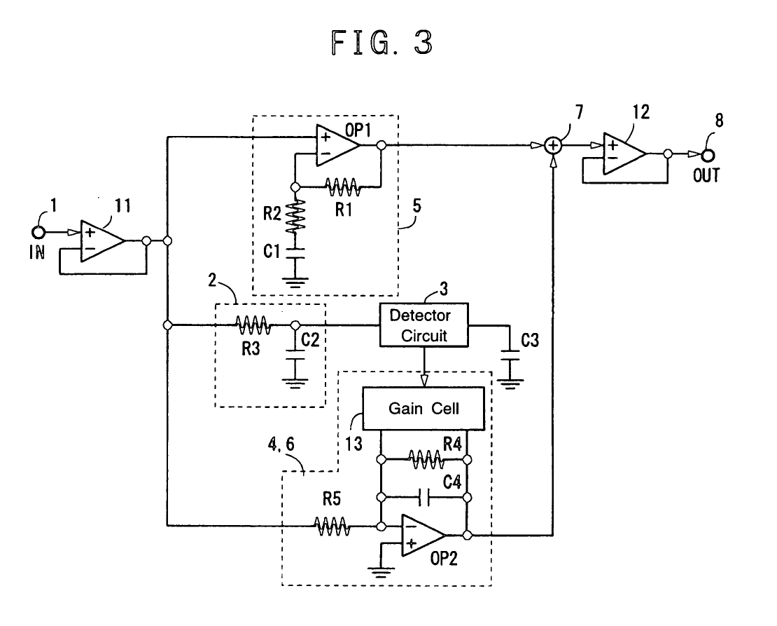

FIG. 3 is a concrete circuit diagram of boost circuit of FIG. 1. Here, input buffer 11 and output buffer 12 were added. Low-pass filter 2 is constituted from resistance R3 and capacitor C2 here. High-pass filter 5 is constituted from resistance R1 and R2, capacitor C1, and operational amplifier OP1. Low-pass filter 4 of variable cut-off frequency and voltage-controlled amplifier 6 consist of operational amplifier OP2, gain cell 13 which works as a variable resistor from which internal resistance changes according to detection power level of detector circuit 3, resistance R4 and R5, and capacitor C4. That is, low-pass filter 4 of variable cut-off frequency and voltage-controlled amplifier 6 are constituted here in one using operational amplifier OP2. High-pass filter 5 boosts only treble and passes signal of other frequency as it is.

### Embodiment 2

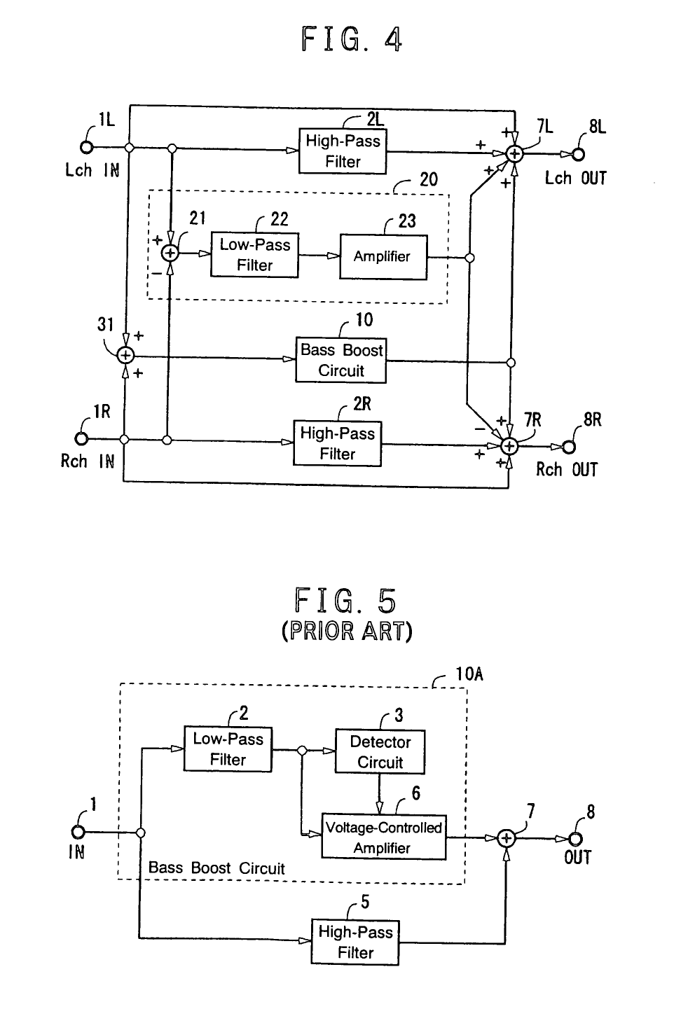

FIG. 4 is a circuit diagram of voice circuit of two channels in which boost circuit and surround-sound generation circuit of embodiment 1 were established. Here, high-pass filters 2L and 2R are connected to both channels, respectively. Bass boost circuit 10 acquires addition signal of both channels with adder 31, inputs and processes it, and is adding it to both channels with Adders 7L and 7R, respectively. In surround-sound generation circuit 20, difference of audio signal of both channels is taken out with subtracter 21, low-pass filter 22 extracts the bass component, and it is amplified with amplifier 23, and it is added to both channels with Adders 7L and 7R, respectively so that it may become same phase to subtraction in the subtracter 21.

Thus, the boost circuit of Embodiment 1 can communalize bass boost circuit 10 to both channels, when applying it to the voice circuit of two channels.

### Embodiment 3

Although voltage-controlled amplifier 6 was connected to the following stage of low-pass filter 4 of variable cut-off frequency in FIG. 1 and low-pass filter 4 of variable cut-off frequency and voltage-controlled amplifier 6 were unified in FIG. 3, composition of connecting low-pass filter 4 of variable cut-off frequency to the following stage of voltage-controlled amplifier 6 may be used. Detector circuit 3 may be replaced with averaging circuit which outputs average value of output signal of low-pass filter 2 or maximizing circuit which outputs maximum value of output signal of low-pass filter 2.

The present invention is not limited to the above-mentioned embodiment and can be variously changed based on meaning of the present invention. For example, voltage-controlled amplifier can be changed into current control type amplifier, or it can also be considered as circuit configuration which processes digital signal.

According to bass boost circuit of the present invention, it does not become over boost state, and sound such as “flop” or “overshoot” is canceled, it will further be hard being fallen out by middle range of frequency, and there is advantage that vocal and the like can tend to be heard, even when small signal is inputted.

It is to be understood that the above-described arrangements are only illustrative of the application of the principles of the present invention. Numerous modifications and alternative arrangements may be devised by those skilled in the art without departing from the scope of the present invention, and the appended claims are intended to cover such modifications and arrangements.

1. A bass boost circuit comprising:
a low-pass filter extracting bass component of incoming signal;
a detector circuit inputting and detecting output signal of said low-pass filter;
a low-pass filter of variable cut-off frequency inputting said incoming signal and outputting bass component, wherein cut-off frequency is controlled according to level of output signal of said detector circuit; and
a voltage-controlled amplifier inputting said output signal of said low-pass filter of variable cut-off frequency and outputting bass boost output signal, wherein gain of said output boost signal is controlled according to level of output signal of said detector circuit.

2. The bass boost circuit of claim 1, wherein said low-pass filter of variable cut-off frequency is controlled by output signal of said detector circuit so that the cut-off frequency becomes low as the output signal level of said low-pass filter is low, and said voltage-controlled amplifier is controlled by output signal of said detector circuit so that the gain becomes high as the output signal level of said low-pass filter is low.

3. The bass boost circuit of claim 2, wherein said detector circuit is selected from the group consisting of an averaging circuit which outputs average value of output signal of said low-pass filter, and a maximizing circuit which outputs maximum of output signal of said low-pass filter.

4. The bass boost circuit of claim 3, wherein said cut-off frequency of said low-pass filter is set up among between 50 Hz and 600 Hz.

5. The bass boost circuit of claim 4, wherein variability range of said cut-off frequency of said low-pass filter of variable cut-off frequency is set up as from 10 to 600 Hz.

6. The bass boost circuit of claim 5, wherein said low-pass filter of variable cut-off frequency and said voltage-controlled amplifier are unified in said bass boost circuit.

7. The bass boost circuit of claim 6, wherein said boost circuit inputs signal which added two audio signal of right and left channel as said incoming signal, and added said bass boost output signal to each audio signal of said right and left channel.

8. The bass boost circuit of claim 1, wherein said detector circuit is selected from the group consisting of an averaging circuit which outputs average value of output signal of said low-pass filter, and a maximizing circuit which outputs maximum of output signal of said low-pass filter.

9. The bass boost circuit of claim 1, wherein said cut-off frequency of said low-pass filter is set up among between 50 Hz and 600 Hz.

10. The bass boost circuit of claim 2, wherein said cut-off frequency of said low-pass filter is set up among between 50 Hz and 600 Hz.

11. The bass boost circuit of claim 1, wherein variability range of said cut-off frequency of said low-pass filter of variable cut-off frequency is set up as from 10 to 600 Hz.

12. The bass boost circuit of claim 2, wherein variability range of said cut-off frequency of said low-pass filter of variable cut-off frequency is set up as from 10 to 600 Hz.

13. The bass boost circuit of claim 3, wherein variability range of said cut-off frequency of said low-pass filter of variable cut-off frequency is set up as from 10 to 600 Hz.

14. The bass boost circuit of claim 1, wherein said low-pass filter of variable cut-off frequency and said voltage-controlled amplifier are unified in said bass boost circuit.

15. The bass boost circuit of claim 2, wherein said low-pass filter of variable cut-off frequency and said voltage-controlled amplifier are unified in said bass boost circuit.

16. The bass boost circuit of claim 3, wherein said low-pass filter of variable cut-off frequency and said voltage-controlled amplifier are unified in said bass boost circuit.

17. The bass boost circuit of claim 4, wherein said low-pass filter of variable cut-off frequency and said voltage-controlled amplifier are unified in said bass boost circuit.

18. The bass boost circuit of claim 1, wherein said boost circuit inputs signal which added two audio signal of right and left channel as said incoming signal, and added said bass boost output signal to each audio signal of said right and left channel.

19. A bass boost circuit comprising:
a low-pass filter extracting bass component of incoming signal;
a detector circuit inputting and detecting output signal of said low-pass filter;
a voltage-controlled amplifier inputting said incoming signal and outputting bass boost output signal, wherein gain of said output boost signal is controlled according to level of output signal of said detector circuit; and
a low-pass filter of variable cut-off frequency inputting said output boost signal of said voltage-controlled amplifier and outputting bass component, wherein cut-off frequency is controlled according to level of output signal of said detector circuit.
